(19) United States
(12) Patent Application Publication
(10) Pub. No.: US 2007/0085588 A1
(43) Pub. Date: Apr. 19, 2007

(54) INTERNAL RESISTOR DEVICE OF INTEGRATED CIRCUIT CHIP

(76) Inventor: Ching-Wu Tseng, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,544

(22) Filed: Nov. 29, 2005

(30) Foreign Application Priority Data
Oct. 19, 2005 (TW) 94136524

(51) Int. Cl. H03B 1/00

(52) U.S. Cl. 327/308; 327/112

(57) ABSTRACT

An internal resistor device of an integrated circuit chip, including a MOS transistor and a logic unit, is provided. The MOS transistor has a drain coupled to an input pin of the integrated circuit chip and a source coupled to a predetermined voltage. The logic unit receives a control signal from the input pin and a driving signal, and then executes a logic operation of the driving and the control signals. The result of the logic operation is provided to the gate of the MOS transistor. When the input pin is floating, the internal resistor device provides a predetermined fixed voltage to internal circuits chip. When the input voltage level is inverse to the predetermined fixed voltage, static current is almost not consumed.

### CROSS-REFERENCE TO RELATED APPLICATION

This application claims the priority benefit of Taiwan application serial no. 94136524, filed on Oct. 19, 2005. All disclosure of the Taiwan application is incorporated herein by reference.

### BACKGROUND OF THE INVENTION

1. Field of the Invention:

This invention relates to a resistor device. More particular, the present invention relates to an internal resistor device of an integrated circuit (IC) chip.

2. Description of Related Art:

The reduction of power consumption for modern portable electronic products and apparatuses is very important. Generally, the portable electronic products and apparatuses are almost with a stand-by mode. The portable electronic products and apparatuses can extend their operating time if operated with a minimum power consumption.

When the IC chip is used in products, input pins of the IC chip are usually designed to have a predetermined voltage level for reducing wiring amount at the product application end. When the product application end does not a signal level to the input pins, an internal resistor can be used to provide a signal level. In this way, ill effects to some signals of the integrated circuit due to floating pins can be avoided.

If the internal resistor is designed in a manner that the floating input pin is pulled up to a high voltage level, the internal resistor will cause a static current consumption when the input pin is connected to a low voltage level in some applications. In contrary, if the internal resistor is designed in a manner that the floating pin is pulled down to a low voltage level, the internal resistor will also cause a static current consumption when the input pin is connected to a high voltage level in some applications.

FIG. 1 shows a conventional internal resistor device. In FIG. 1, “IN” is an input pin connected to the exterior of an IC chip and “OUT” represents an output pin connected to the interior of the IC chip. The default of the internal resistor device is designed to have a high voltage level, which means that the output pin is pulled up to the high voltage level when the input pin IN is floating. This is a simple form of a resistor, in which a PMOS transistor 110 is turned on to pull the output pin OUT to the high voltage level. If an turn-on resistance of the above internal resistor device is 30 kΩ, a voltage VDD is 3 Volts and the input pin is grounded, a current of 100 μA will flow to the input pin, causing a power consumption of about 1 mW. The power consumption can be reduced by making the internal resistor device have a higher turn-on resistance, but a ability for pulling up the voltage is clearly decreased. As a result, the input pin is easily coupled with external signals to cause error function.

### SUMMARY OF THE INVENTION

According to the foregoing description, an object of this invention is to provide an internal resistor device capable of providing a predetermined voltage level when an input pin of an IC chip is floating. In addition, the internal resistor device can increase a driving capability of the IC chip without being affected by noise signals. Furthermore, internal resistor device can also decrease a static current consumption to reduce a power consumption of the entire IC chip.

According to the above objects, the present invention provides an internal resistor device for an integral circuit chip, comprising a MOS transistor and a logic unit. The MOS transistor has a drain coupled to an input pin of the integral circuit chip and a source coupled to a predetermined voltage level. The logic unit is used for receiving a control signal from the input pin and a driving signal. The logic unit executes a logic operation of the driving and the control signals, and then outputs a result of the logic operation to a gate of the MOS transistor.

In one embodiment of the present invention, the internal resistor device can further comprises a buffer device coupled between the input pin and the logic unit, for avoiding a noise occurred on the input pin.

In one embodiment of the present invention, the MOS transistor is a PMOS transistor, the predetermined voltage level is obtained from a voltage source, the logic unit is a NOR gate and the driving signal is a positive pulse signal.

In one embodiment of the present invention, the MOS transistor is an NMOS transistor whose source is grounded, the logic unit is a NAND gate, and the driving signal is a negative pulse signal.

According to the internal resistor device described above, no matter the input pin is at high level, low level or floating, the static current consumption never occurs or only in a very short instant. Therefore, the power consumption of the entire chip can be reduced. In addition, since the static current consumption is extremely small, the internal resistance of the MOS transistor can be set smaller to increase the driving capability of the IC chip without affecting by noise signals.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings.

FIG. 1 shows a conventional internal resistor device.

FIG. 2 is a block diagram showing an internal resistor device for an integrated circuit chip according to one embodiment of the present invention.

FIG. 3 is a circuit diagram showing an internal resistor device for an integrated circuit chip according to one embodiment of the present invention.

FIG. 4 is a timing diagram showing a control signal input to an input pin is at high level according to one embodiment of the present invention.

FIG. 5 is a timing diagram showing a control signal input to an input pin is at low level according to one embodiment of the present invention.

FIG. 6 is a timing diagram showing a control signal input to an input pin is floating according to one embodiment of the present invention.

FIGS. 7-8 and 10-12 are circuit diagrams showing different internal resistor devices for an integrated circuit chip according to other embodiments of the present invention.

FIG. 9 is a timing diagram showing a control signal input to an input pin is at high level according to one embodiment of the present invention.

### DESCRIPTION OF THE PREFERRED EMBODIMENT

The present invention provides an internal resistor device, which will be described in detail according to following embodiments. According to the internal resistor device, the power consumption of the internal resistor in the integrated circuit chip and the capability for avoiding noise can be increased.

FIG. 2 is a block diagram sowing an internal resistor device of an integrated circuit chip according to one embodiment of the present invention. In FIG. 2, “IN” represents an input pin connected the exterior of the IC chip, and “OUT” represents an output pin connected the interior of the IC chip. The internal resistor device comprises a MOS transistor 210 and a logic unit 202. The logic unit 202 receives a driving signal V1 and a control signal 206, and the control signal 206 comes from the input pin IN and then passes through a buffer device 204 to the logic unit 202. The logic unit 202 executes a logic operation using the driving signal V1 and the control signal 206, and a result 208 of the logic operation is output to the gate of the MOS transistor 210. According to the above result 208 provided to the gate, the MOS transistor 210 is turned on and acts as a resistor. Meanwhile, the voltage level of the input pin (OUT) of the IC chip, coupled to the drain of the MOS transistor 210, is pulled up to a predetermined voltage level 212. Several examples will be provided for explaining the internal resistor device in FIG. 2.

FIG. 3 is a circuit diagram of the internal resistor device of the IC chip according to one embodiment of the present invention. In FIG. 3, “IN1” represents an input pin connected the exterior of the IC chip, and “OUT1 ” represents an output pin connected the interior of the IC chip. Referring to FIG. 3, an NOR gate 302 is equivalent to the logic unit 202 shown in FIG. 2, and the numerals “306” and “308” are respectively equivalent to the control signal 206 and the result 208 shown in FIG. 2. The PMOS transistor 310 is equivalent to the MOS transistor 210 shown in FIG. 2. “IN1” and “OUT1” are respectively equivalent to “IN” and “OUT” shown in FIG. 2. In the embodiment, the driving signal V1 is input to one input end of the NOR gate 302 and the other input end of the NOR gate 302 is coupled to the input pin IN1. The output end of the NOR gate 302 is coupled to the gate of the PMOS transistor 310. The source of the PMOS transistor 310 is coupled to a voltage source VDD, and the drain of the PMOS transistor 310 is coupled to the output pin OUT1. When the input pin IN1 is floating, the output pin OUT1 of the internal resistor device of FIG. 3 is latched to a predetermined high voltage level VDD.

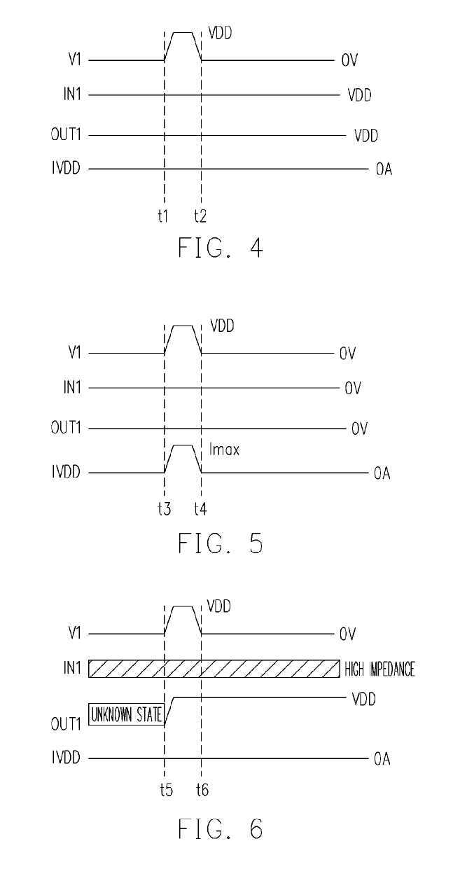

FIG. 4 is a timing diagram showing an operation when the input pin IN1 is fixed at the high level by using a pin option manner for meeting requirements. At time tl, the driving signal V1 is transient to the high level and the output of the NOR gate 302 becomes low level. Therefore, the PMOS transistor 310 is turned on and the output pin OUT1 is pulled up to the high level. At time t2, the driving signal V1 is at low level. Since the input pin IN1 is at high level, the PMOS transistor 310 is still turned on and the output pin OUT 1 is kept at high level. In the above process, the operational current IVDD of the PMOS transistor 310 is zero.

FIG. 5 is a timing diagram showing an operation when the input pin IN1 is fixed at low level by using the pin option manner for meeting requirement. At time t3, the driving signal V1 becomes high level, so that the output 308 of the NOR gate 302 becomes low level to turn on the PMOS transistor 310. At this time, since the output pin OUT1 is at low level, the PMOS transistor 310 consumes a power to create a current Imax. At time t4, the driving signal V1 is at low level. Since the input pin IN1 is at low level, the output 308 of the NOR gate 302 turns off the PMOS transistor 310, so that the operational current of the PMOS transistor 310 becomes zero.

If the driving signal V1 is a periodic pulse signal with a period of 16 ms, the duration for each positive pulse is 8 μs and a turned-on resistance of the PMOS transistor 310 is 30 kΩ. When VDD is 3 Volts and the input pin is grounded, an average current consumption is 50 nA and a power consumption is merely 15 μW. If the driving signal V1 is a Power ON Reset signal, the usual power consumption after the power is turned on is zero.

FIG. 6 is a timing diagram for an operation that the input pin IN1 in FIG. 3 is floating. Before time t5, the state of the output pin OUT1 is unknown. However, at time t5, the positive pulse of the driving signal V1 turns on the PMOS transistor 310, so that the voltage on the output pin OUT1 is pulled up to a high level. Since the input pin IN1 is connected to the output pin OUT1, the voltage on the input pin IN1 is also a high level. At time t6, the driving signal V1 becomes low level. The PMOS transistor 310 is still turned on since the input pin IN1 is at high level, so that the output pin OUT1 is latched to a high level. In the above process, the operational current lVDD is still zero.

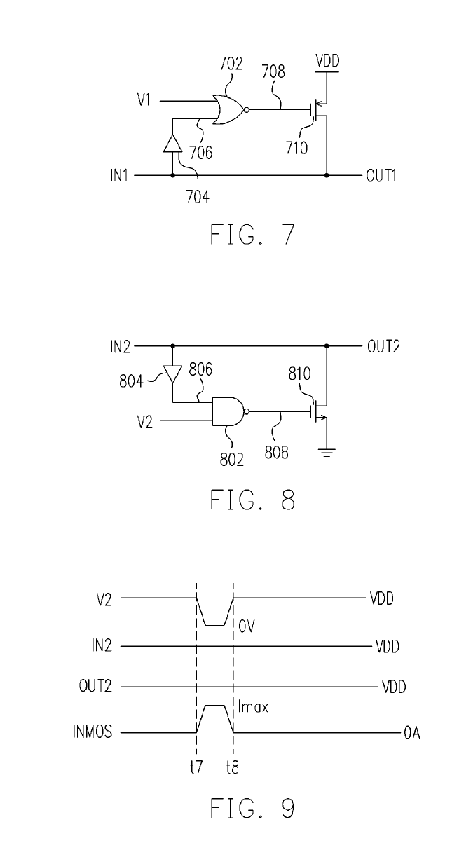

Those skilled in this art can modify the embodiment of FIG. 3 based on requirements. For example, as shown in FIG. 7, a buffer device can be further set between the logic unit and the input pin for avoiding noise on the input pin. FIG. 7 is a circuit diagram showing an internal resistor device for an integrated circuit chip according to another embodiment of the present invention. In FIG. 7, “IN1 ” represents an input pin connected to the exterior of the IC chip, and “OUT1 ” represents an output pin connected to the internal of the IC chip. A NOR gate 702 functions as the logic unit 202 of FIG. 2, a signal 706 is equivalent to the control signal 206 of FIG. 2, a operation result 708 is equivalent to the operation result 208 of FIG. 2, a PMOS transistor 710 is equivalent to the MOS transistor 210, a buffer 704 functions as the buffer device 204 of FIG. 2, “IN1 ” is equivalent to the input pin IN of FIG. 2 and “OUT1 ” is equivalent to the output pin OUT of FIG. 2. Since the buffer 704 is used to buffer the signal, the circuit operation is the same as the circuit shown in FIG. 3 and its corresponding description is omitted.

FIG. 8 is a circuit diagram of the internal resistor device of the IC chip according to another embodiment of the present invention. In FIG. 8, “IN2” represents an input pin connected to the exterior of the IC chip, and “OUT2” represents an output pin connected to the internal of the IC chip. Referring to FIG. 8, A NAND gate 802 functions as the logic unit 202 of FIG. 2, a signal 806 is equivalent to the control signal 206 of FIG. 2, a operation result 808 is equivalent to the operation result 208 of FIG. 2, an NMOS transistor 810 is equivalent to the MOS transistor 210, a buffer 804 functions as the buffer device 204 of FIG. 2, “IN2” is equivalent to the input pin IN of FIG. 2 and “OUT2” is equivalent to the output pin OUT of FIG. 2. In FIG. 8, the internal resistor device can latch the output pin OUT 2 to a predetermined low voltage level, such as a ground (GND) level, when the input pin IN2 is floating.

In this embodiment, one input of the NAND gate 802 receives a driving signal V2, and another input is coupled to the input pin IN2. An output of the NAND gate 802 is coupled to the gate of the NMOS transistor 810. The source of the transistor 810 is coupled to the ground level and the drain is coupled to the output pin OUT2. FIG. 9 is a timing diagram showing an operation when the input pin IN2 has to be fixed at high level by using the pin option manner in some applications. At time t7, the output signal 808 of the NAND gate 802 turns on the NMOS transistor 810 because of the negative pulse of the driving signal V2 (from high level to low level). At this time, the drain of the NMOS transistor 810 is at high level, and the source is at low level. As a result, the NMOS transistor 810 consumes a power and the operational current I_{NMOS} flowing through the NMOS transistor 810 is increased up to Imax. At time t8, the driving signal V2 becomes high level. Since the input pin IN2 is also at high level, the output signal 808 of the NAND gate 802 is transient to low level. As a result, the NMOS transistor 810 is turned off and the operational current I_{NMOS}becomes zero. In other words, when the driving signal V2 is at high level, no power is consumed on the internal resistor device.

After reviewing the description corresponding to FIGS. 2 to 9, those skilled in this art can easily deduce the following conclusions. When the input pin IN2 in FIG. 8 is fixed at low level or floating, the internal resistor device in FIG. 8 has no power consumption. Namely, the operational current I_{MOS} of the transistor 810 is always zero. Therefore, when the input pin IN2 in FIG. 8 is fixed at low level or floating, the process caused by the driving signal V2 is not redundantly described.

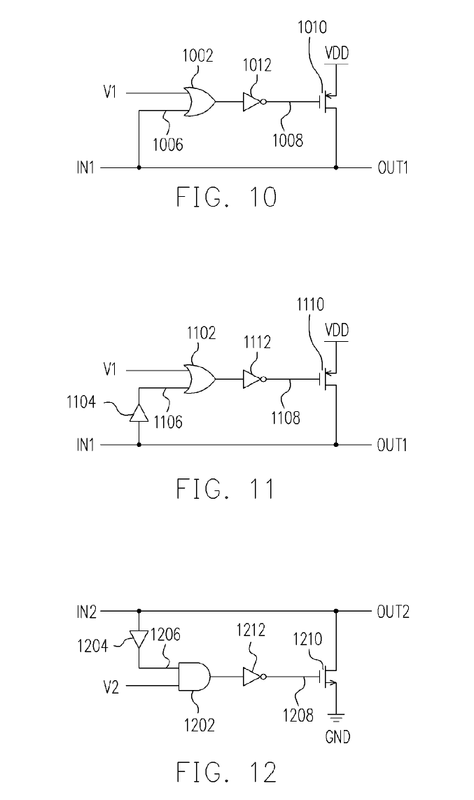

Those skilled in this art can modify the embodiment of FIG. 3 based on requirements. For example, as shown in FIG. 10, the NOR gate 302 can be replaced by an inverter 1012 and an OR gate 1002 for performing the same function. FIG. 10 is a circuit diagram showing an internal resistor device for an integrated circuit chip according to another embodiment of the present invention. In FIG. 10, “IN1” represents an input pin connected to the exterior of the IC chip, and “OUT1” represents an output pin connected to the internal of the IC chip. Referring to FIG. 10, the inverter 1012 and the OR gate 1002 functions as the logic unit 202 of FIG. 2, a signal 1006 is equivalent to the control signal 206 of FIG. 2, a operation result 1008 is equivalent to the operation result 208 of FIG. 2, a PMOS transistor 1010 is equivalent to the MOS transistor 210, “IN1” is equivalent to the input pin IN of FIG. 2 and “OUT1” is equivalent to the output pin OUT of FIG. 2. Since the circuit formed by the inverter 1012 and the OR gate 1002 has the same function as the NOR gate 302, the operation of the internal resistor device of FIG. 10 is the same as the circuit shown in FIG. 3 and its corresponding description is omitted.

Those skilled in this art can modify the embodiment of FIG. 10 based on requirements. For example, as shown in FIG. 11, a buffer device can be further set between the logic unit and the input pin for avoiding noise on the input pin. FIG. 11 is a circuit diagram showing an internal resistor device for an integrated circuit chip according to another embodiment of the present invention. In FIG. 11, “IN1” represents an input pin connected to the exterior of the IC chip, and “OUT1” represents an output pin connected to the internal of the IC chip. Referring to FIG. 11, the inverter 1112 and the OR gate 1102 functions as the logic unit 202 of FIG. 2, a signal 1106 is equivalent to the control signal 206 of FIG. 2, a operation result 1108 is equivalent to the operation result 208 of FIG. 2, a PMOS transistor 1110 is equivalent to the MOS transistor 210, a buffer 1104 functions as the buffer device 204 of FIG. 2 “IN1” is equivalent to the input pin IN of FIG. 2 and “OUT1 ” is equivalent to the output pin OUT of FIG. 2. Since the buffer 1104 is used to buffer the signal, the circuit operation is the same as the circuits shown in FIGS. 3 and 10, and its corresponding description is omitted.

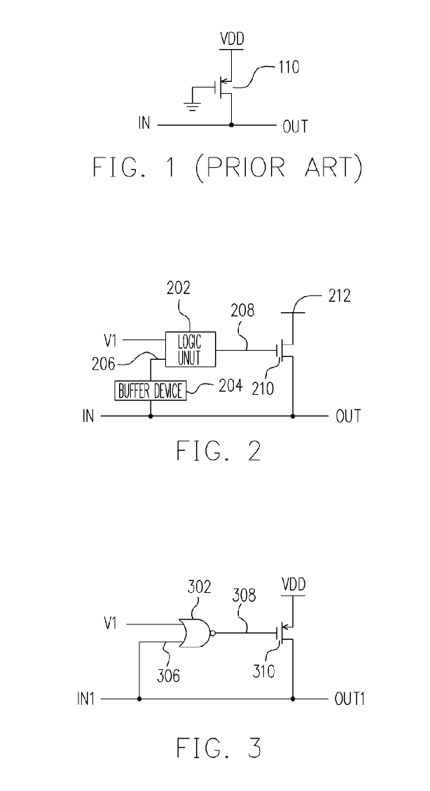

Those skilled in this art can modify the embodiment of FIG. 8 based on requirements. For example, as shown in FIG. 12, the NAND gate 802 can be replaced by an inverter 1212 and an AND gate 1202 for performing the same function. FIG. 12 is a circuit diagram showing an internal resistor device for an integrated circuit chip according to another embodiment of the present invention. In FIG. 1 2, “IN2” represents an input pin connected to the exterior of the IC chip, and “OUT2” represents an output pin connected to the internal of the IC chip. Referring to FIG. 12, the inverter 1212 and the AND gate 1202 functions as the logic unit 202 of FIG. 2, a signal 1206 is equivalent to the control signal 206 of FIG. 2, a operation result 1208 is equivalent to the operation result 208 of FIG. 2, an NMOS transistor 1210 is equivalent to the MOS transistor 210, “IN2” is equivalent to the input pin IN of FIG. 2 and “OUT2” is equivalent to the output pin OUT of FIG. 2. Since the circuit formed by the inverter 1212 and the AND gate 1202 has the same function as the NAND gate 802, the operation of the internal resistor device of FIG. 12 is the same as the circuit shown in FIG. 8 and its corresponding description is omitted.

In summary, according to the internal resistor device of the IC chip, no matter the input pin is at high level, low level or floating, the static current consumption never occurs or only in a very short instant. Therefore, the power consumption of the entire chip can be reduced. In addition, since the static current consumption is extremely small, the internal resistance of the MOS transistor can be set smaller to increase the driving capability of the IC chip without affecting by noise signals.

While the present invention has been described with a preferred embodiment, this description is not intended to limit our invention. Various modifications of the embodiment will be apparent to those skilled in the art. It is therefore contemplated that the appended claims will cover any such modifications or embodiments as fall within the true scope of the invention.

What is claimed is:

1. An internal resistor device for an integral circuit chip, comprising:
a MOS transistor, with a drain coupled to an input pin of the integral circuit chip and a source coupled to a predetermined voltage level; and
a logic unit, for receiving a control signal from the input pin and a driving signal, wherein the logic unit executes a logic operation of the driving and the control signals, and then outputs a result of the logic operation to a gate of the MOS transistor.

2. The internal resistor device of claim 1, further comprising:
a buffer device, coupled between the input pin and the logic unit, for avoiding a noise of the input pin.

3. The internal resistor device of claim 1, wherein the MOS transistor is a PMOS transistor.

4. The internal resistor device of claim 3, wherein the predetermined voltage level is obtained from a voltage source.

5. The internal resistor device of claim 3, wherein the logic unit is a NOR gate.

6. The internal resistor device of claim 3, wherein the logic unit comprises:
an OR gate for receiving the driving signal and the control signal; and
an inverter, coupled between an output end of the OR gate and the gate of the MOS transistor.

7. The internal resistor device of claim 3, wherein the driving signal is a pulse signal.

8. The internal resistor device of claim 7, wherein the driving signal is a positive pulse signal.

9. The internal resistor device of claim 7, wherein the driving signal is a periodic signal.

10. The internal resistor device of claim 1, wherein the MOS transistor is an NMOS transistor.

11. The internal resistor device of claim 10, wherein the source of the NMOS transistor is grounded.

12. The internal resistor device of claim 10, wherein the logic unit is a NAND gate.

13. The internal resistor device of claim 10, wherein the logic unit comprises:
an AND gate for receiving the driving signal and the control signal; and
an inverter, coupled between an output end of the AND gate and the gate of the MOS transistor.

14. The internal resistor device of claim 10, wherein the driving signal is a pulse signal.

15. The internal resistor device of claim 14, wherein the driving signal is a negative pulse signal.

16. The internal resistor device of claim 14, wherein the driving signal is a periodic signal.
